(19) United States
(12) Patent Application Publication
(10) Pub. No.: US 2014/0340598 A1
(43) Pub. Date: Nov. 20, 2014

(54) TOUCH PANEL

(71) Applicants: Allan Johansson, Lund (SE); Jonas Jönsson, Genarp (SE); Damir Kajic, Lund (SE); Tomas Kulle, Hjarup (SE); Magnus Midholt, Lund (SE); Björn Rosqvist, Lund (SE); Peter Åberg, Vinslov (SE)

(72) Inventors: Allan Johansson, Lund (SE); Jonas Jönsson, Genarp (SE); Damir Kajic, Lund (SE); Tomas Kulle, Hjarup (SE); Magnus Midholt, Lund (SE); Björn Rosqvist, Lund (SE); Peter Åberg, Vinslov (SE)

(73) Assignee: Sony Mobile Communications AB, Lund (SE)

(21) Appl. No.: 14/344,198

(22) PCT Filed: Jan. 19, 2012
(86) PCT No.: PCT/EP2012/000239

§ 371 Date: Mar. 11, 2014

(51) Int. Cl. G06F 1/16; H05K 1/02

(52) U.S. Cl. CPC G06F 1/1692; H05K 1/0274; H05K 1/0298; H05K 1/0213
USPC 349/12; 174/251

(57) ABSTRACT

A touch panel is provided. The touch panel comprises a carrier panel (400), a first electrically conductive layer (100), an electrically isolating layer (200), and a second electrically conductive layer (300). The first electrically conductive layer (100) is arranged on a surface of the carrier panel (400) and comprises a first pattern of a plurality of electrically separated areas (11-85). The electrically isolating layer (200) is arranged on the first electrically conductive layer (100) and comprises openings (201) providing access to at least some of the electrically separated areas (11-85) through the electrically isolating layer (200). The second electrically conductive layer (300) is arranged on the electrically isolating layer (200) and comprises a second pattern comprising a plurality of electrically separated areas (301, 302). The plurality of electrically separated areas (301, 302) of the second pattern comprises at least one bridging area (301) electrically coupling at least two of the plurality of electrically separated areas (11-54) of the first pattern through at least two of the openings (201) of the electrically isolating layer (200), and a shielding area (302) electrically isolated from the plurality of electrically separated areas (11-85) of the first pattern.

### FIELD OF THE INVENTION

The present application relates to a touch panel, especially to a capacitive touch panel to be used in combination with a display to form a so called touch screen for a user interface device of for example a mobile telephone.

### BACKGROUND OF THE INVENTION

Touch panels are known in the art for controlling devices via a user interface. The touch panel may be arranged on top of a display forming a so called touch screen. Such a touch screen provides a very intuitive way of operating the device. Information may be displayed on the display and in response to the information displayed on the display the user may touch the display for initiating actions or operations. The touch panel may work by detecting a change of capacity when the user approaches or touches the surface of the touch panel. Therefore, the touch panel may provide an array or grid of electrodes and a control unit may detect an approach of a finger of the user to a certain position on the touch panel by a change of capacitance of the electrodes. However, when the electrodes of the touch panel are arranged in close vicinity to the display, the electrically driven display and a control for driving the display may influence the electrodes such that the capacitive detection of the user touching the touch panel may be disturbed.

Therefore, there is a need to provide a more robust and reliable touch panel to be used for example in combination with a display, especially for consumer products like mobile phones.

### SUMMARY OF THE INVENTION

According to the present invention, this object is achieved by a touch panel as defined in claim 1, a user interface device as defined in claim 12, and a mobile device as defined in claim 15. The dependent claims define preferred and advantageous embodiments of the invention.

According to an aspect of the present invention, a touch panel comprises a carrier panel, for example a transparent window panel made of glass or resin, and a first electrically conductive layer arranged on a surface of the carrier panel. The first electrically conductive layer comprises a first pattern of a plurality of electrically separated areas. The touch panel comprises furthermore an electrically isolating layer arranged on the first electrically conductive layer. The electrically isolating layer comprises openings providing access to at least some of the electrically separated areas of the first electrically conductive layer through the electrically isolating layer. The touch panel comprises furthermore a second electrically conductive layer which is arranged on the electrically isolating layer. The second electrically conductive layer comprises a second pattern comprising a plurality of electrically separated areas. The plurality of electrically separated areas of the second pattern comprises at least one bridging area which electrically couples at least two of the plurality of electrically separated areas of the first pattern through at least two of the openings of the electrically isolating layer. The plurality of electrically separated areas of the second pattern comprises furthermore a shielding area for electrically shielding the first pattern of the first electrically conductive layer. The shielding area is electrically isolated from the plurality of electrically separated areas of the first pattern of the first electrically conducive layer. The electrically separated areas of the first electrically conductive layer may comprise electrodes for detecting a capacitive change when a user is approaching the touch panel. The electrodes may be coupled to each other or wired to a connection area of the touch panel within the first electrically conductive layer or via the bridging areas in the second electrically conductive layer such that electrically isolated crossing points for wiring the electrodes may be accomplished. The shielding area of the second electrically conductive layer shields the electrodes from electrical disturbances such that the touch panel may be arranged in close vicinity to a display, for example a liquid crystal display without having the effect that the display disturbs the capacitive sensoring of the touch panel. As the shielding area is part of the second electrically conductive layer which may be anyway necessary for the bridging connections or crossing points, no additional separate shielding layer is needed. This reduces costs for the touch panel. Due to the shielding area the touch panel may be arranged directly on top of a front panel of the display and the carrier panel may comprise a front window made of glass or resin such that a minimum of components and layers is needed for a touch sensitive display. This may reduce not only the cost, but also installation space needed for accommodating the touch sensitive display in a mobile device, for example a mobile phone or a smart phone.

According to an embodiment, the shielding area covers essentially the whole first pattern apart from the at least one bridging area. The electrodes of the touch panel comprised in the first electrically conductive layer are typically arranged in a matrix or a grid. Therefore, only a few small bridging areas are necessary to connect the electrodes appropriately. The remaining space of the second electrically conductive layer is therefore available for serving as the shielding area. It is to be understood that the shielding area is electrically isolated from the bridging areas as well as from the electrodes of the first electrically conductive layer. Due to the large dimension of the shielding area in the second electrically conductive layer, an appropriate shielding of the electrodes in the first electrically conductive layer can be achieved.

According to a further embodiment, the first and the second electrically conductive areas are made of a visually transparent material. The visually transparent material may comprise for example indium tin oxide (ITO) or graphene. Thin layers of these materials absorb only a very small amount of light such that a display arranged behind the touch panel can be regularly read through the touch panel.

According to an embodiment, the plurality of electrically separated areas of the first pattern comprises a plurality of first fields arranged in rows and a plurality of second fields arranged in columns. Fields of the first fields in a common row are electrically coupled via connections within the first electrically conductive layer and fields of the second fields in a common column are electrically coupled via the at least one bridging area of the second electrically conductive layer. The first and second fields may serve as capacitance detecting electrodes. By arranging the first fields and the second fields in a matrix of rows and columns a position where a user touches the touch panel can be easily determined. Therefore, the electrodes or fields within one column have to be electrically coupled and the fields or electrodes within one row have to be electrically coupled. Therefore, crossing points may occur for wiring the rows and columns. Crossing conductive lines at the crossing points can be easily accomplished by a bridging area which is arranged across a line or connection within the first electrically conductive layer. Such a bridging area is also called “jumper”. The bridging area is electrically isolated from the connection or line within the first electrically conductive layer to be crossed by the electrically isolating layer. The bridging area is electrically coupled to the second fields through openings in the electrically isolating layer.

According to an embodiment, the first fields and the second fields each have a diamond shape. However, any other shape may be appropriate, for example a square shape or a circular shape.

The electrically isolating layer may be sandwiched between the first and second electrically conductive layers. Furthermore, the electrically isolating layer, the first electrically conductive layer, and the second electrically conductive layer may be arranged on a same side or surface of the carrier panel. The carrier panel may comprise a front window of for example a mobile device. The surface opposite to the surface on which the layers are arranged, may constitute an outer surface of the touch panel arrangement at an outside of the mobile device for being touched by a user. Therefore, the carrier panel does not only support the electrically conducting an isolating layers but provides also a protection for these layers. The carrier panel may comprise a transparent material such that a display which is arranged behind the carrier panel is visible through the carrier panel and the layers arranged on the carrier panel.

According to an embodiment, the openings of the electrically isolating layer are cutouts formed in the electrically isolating layer. However, the electrically isolating layer may be formed by printing an isolating material on the first electrically conductive layer, whereby the openings are not printed or protected from printing.

According to another aspect of the present invention a user interface device is provided. The device comprises a display configured to display information for a user on a display area of a front panel of the display, and a touch panel as described above. The touch panel may be arranged on the front panel of the display such that the second electrically conductive layer is arranged on the front panel. The shielding area may be coupled to a fixed electrical potential. Thus, electromagnetic fields from the display may be reliably shielded by the shielding area such that an operation of the touch panel is not influenced by an operation of the display.

According to an embodiment, the user interface device comprises furthermore a control unit coupled to the plurality of electrically separated areas of the first pattern and configured to determine based on a change of capacity of each of the plurality of electrically separated areas a position where a user approaches or touches the touch panel.

According to another aspect of the present invention, a mobile device is provided comprising the user interface as defined above. The mobile device may comprise a mobile phone, a personal digital assistant, a media player, or a navigation system.

Although specific features described in the above summary and the following detailed description are described in connection with specific embodiments and aspects, it is to be understood that the features of the embodiments and aspects my be combined with each other unless specifically noted otherwise.

### BRIEF DESCRIPTION OF THE DRAWINGS

The invention will now be described in more detail with reference to the accompanying drawings.

FIG. 1 schematically shows a first electrically conductive layer for a touch panel according to an embodiment of the present invention.

FIG. 2 shows an electrically isolating layer for a touch panel according to an embodiment of the present invention.

FIG. 3 shows the electrically isolating layer of FIG. 2 arranged on the first electrically conductive layer of FIG. 1.

FIG. 4 shows a second electrically conductive layer for a touch panel according to an embodiment of the present invention.

FIG. 5 shows the second electrically conductive layer of FIG. 4 arranged on the electrically isolating layer of FIG. 2 arranged on the first electrically conductive layer of FIG. 1.

FIG. 6 shows a schematic cross-sectional view of a user interface device according to an embodiment of the present invention.

FIG. 7 shows as schematic view of a mobile device according to an embodiment of the present invention.

### DETAILED DESCRIPTION OF PREFERRED EMBODIMENTS

In the following, exemplary embodiments of the invention will be described in more detail. It has to be understood that the following description is given only for the purpose of illustrating the principles of the invention and is not to be taken in a limiting sense. Rather, the scope of the invention is defined only by the appended claims and is not intended to be limited by the exemplary embodiments hereinafter.

It is to be understood that the features of the various exemplary embodiments described herein may be combined with each other unless specifically noted otherwise. Same reference signs in the various drawings and the following description refer to similar or identical components.

In the following, a structure of a touch panel will be described in more detail. The touch panel comprises a carrier panel, a first electrically conductive layer arranged on a surface of the carrier panel, an electrically isolating layer arranged on the first electrically conductive layer, and a second electrically conductive layer arranged on the electrically isolating layer. The structure of the single layers will be described in more detail in the following.

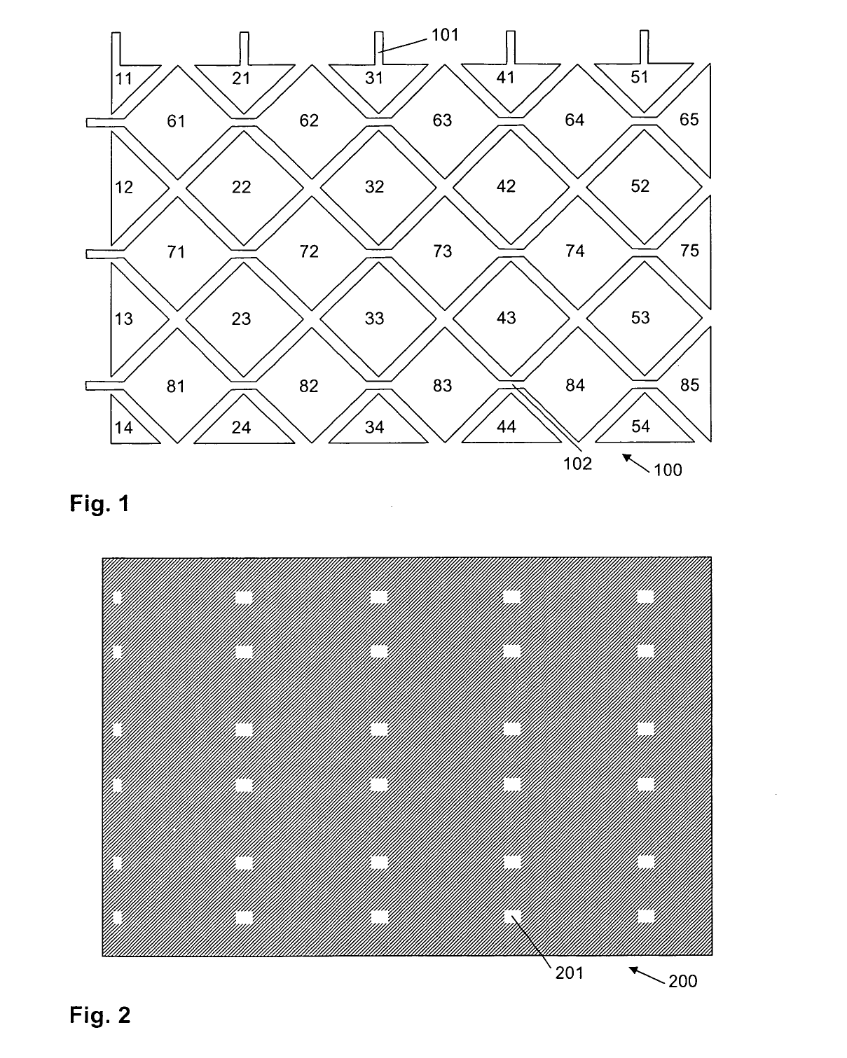

FIG. 1 shows the first electrically conductive layer 100. The layer 100 comprises a pattern of fields 11-85. The fields are arranged in rows and column. The fields 11-14 constitute a first column. The fields 21-24 constitute a second column. The fields 31-35, 41-44, and 51-54 constitute a third, a fourth, and a fifth column, respectively. The fields 61-65 constitute a first row, the fields 71-75 a second row, and the fields 81-85 a third row. The number of fields, rows and columns is only exemplary and other numbers of fields, rows and columns and even a different arrangement may be used. The fields within one row are electrically coupled via connections 102. Only one connection 102 is designated by a reference sign, although FIG. 1 shows twelve connections 102. Thus, the fields 61-65 form one area which is electrically separated from the other fields in the layer 100. Each row and each column has a connector strip 101 for coupling the rows and columns with a control unit. Only one connector strip 101 is designated by a reference sign, although FIG. 1 shows eight connector strips 101. The fields within one row, for example the fields 11-14, are electrically connected to each other via so-called jumpers in the second electrically conductive layer as will be explained in connection with FIGS. 2-5. However, the fields within one row are electrically isolated from the fields of the other rows and the fields of the columns. The arrangement of the fields 11-85 may be used in connection with the control unit to detect a position where a user touches or approaches to the touch panel by detecting a change of capacity in the area where the user approaches or touches the touch panel. The method, how to detect when a user approaches or touches a touch panel due to a change in capacity, is known in the art and will therefore not be described in detail herein. The fields 11-85, the connections 102 and the connectors 101 may be made of an electrically conductive and visually transparent material, for example indium tin oxide (ITO) or graphene. A method, how to deposit such a material on the carrier panel of the touch panel, for example on a glass panel is known in the art and will therefore not be described in detail herein.

FIG. 2 shows the electrically isolating layer 200 which is to be arranged on top of the first electrically conductive layer 100. The electrically isolated layer 200 comprises openings 201 such that the fields 11-54 of the columns of the first electrically conductive layer 100 are reachable through the openings. In FIG. 2 only one of the openings is designated with a reference sign, although the electrically isolating layer 200 comprises in this embodiment thirty openings 201.

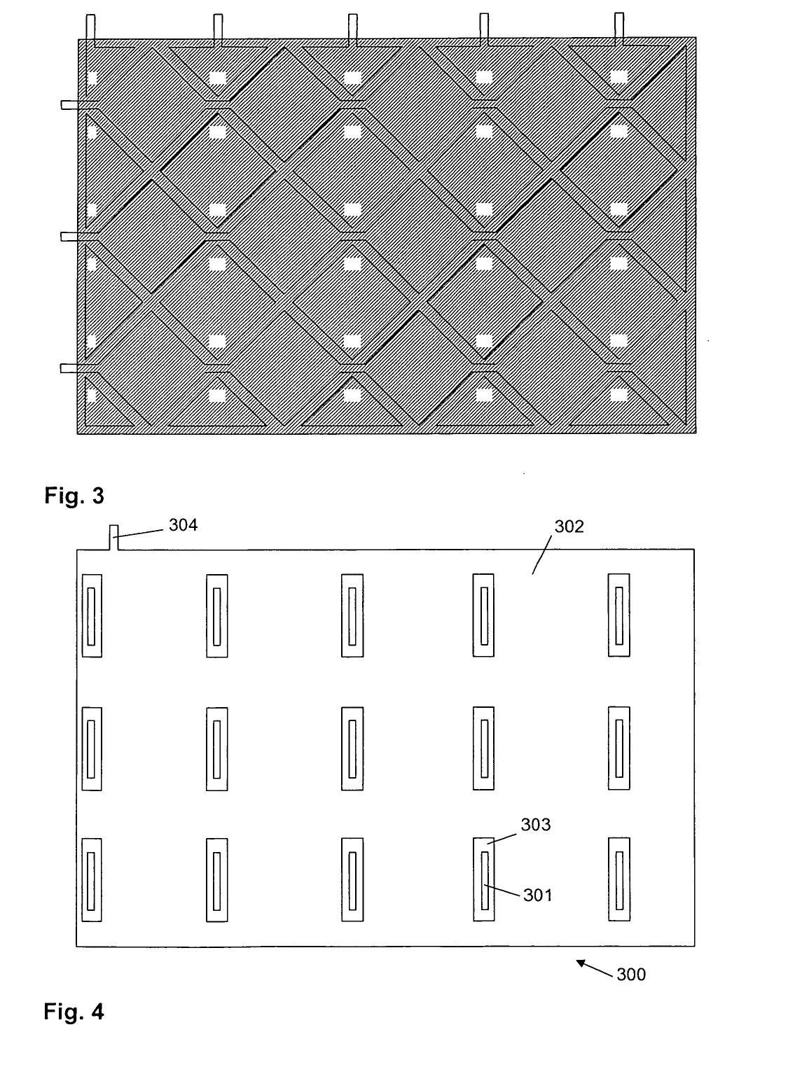

FIG. 3 shows the electrically isolating layer 200 arranged on the first electrically conductive layer 100. As can be seen, the openings 201 are arranged such that the fields 11-54 of the columns are reachable. Furthermore, the openings 201 are arranged such that bridging connections may be arranged such on the electrically isolating layer 200 that two neighboring fields 11-54 within one row can be electrically connected through the openings 201.

FIG. 4 shows the second electrically conductive layer 300 comprising bridging connections 301 which are arranged such that neighboring fields 11-54 in the first electrically conductive layer 100 are electrically connected via the bridging connections 301 through the openings 201 in the electrically isolating layer 200. The second electrically conductive layer 300 comprises furthermore a shielding area 302 which covers essentially all fields 11-85 when being arranged on the top of the first electrically conductive layer 100 and the electrically isolating layer 200. However, the shielding area 302 does not cover the bridging connections 301 and a space 303 surrounding each of the bridging connections 301. Therefore, the shielding area 302 is electrically isolated from the bridging connections 301 and does not come into with any of the fields 11-85 through the openings 201. The shielding area 302 comprises furthermore a connector strip 304 for coupling the shielding area 302 to for example a fixed electrical potential, for example to ground, or to an active driven shielding signal, for example to an AC driven shielding signal. Thus, the shielding area 302 provides an electromagnetic shielding protecting the fields 11-85 from electromagnetic disturbances.

FIG. 5 shows the stacked arrangement of the first electrically conductive layer 100, the electrically isolating layer 200 and the second electrically conductive layer 300. The electrically isolating layer 200 is sandwiched between the first and second electrically conductive layers 100, 300. As can be seen, at crossing points 501 the connection 102 connecting fields of a common row crosses a bridging connection 301 connecting fields of a common column without an electrical connection between connection 102 and bridging connection 301 due to the electrically isolating layer 200. Furthermore, as can be seen from FIG. 5, an essential area of the fields 11-85 is covered and thereby protected by the shielding area 302.

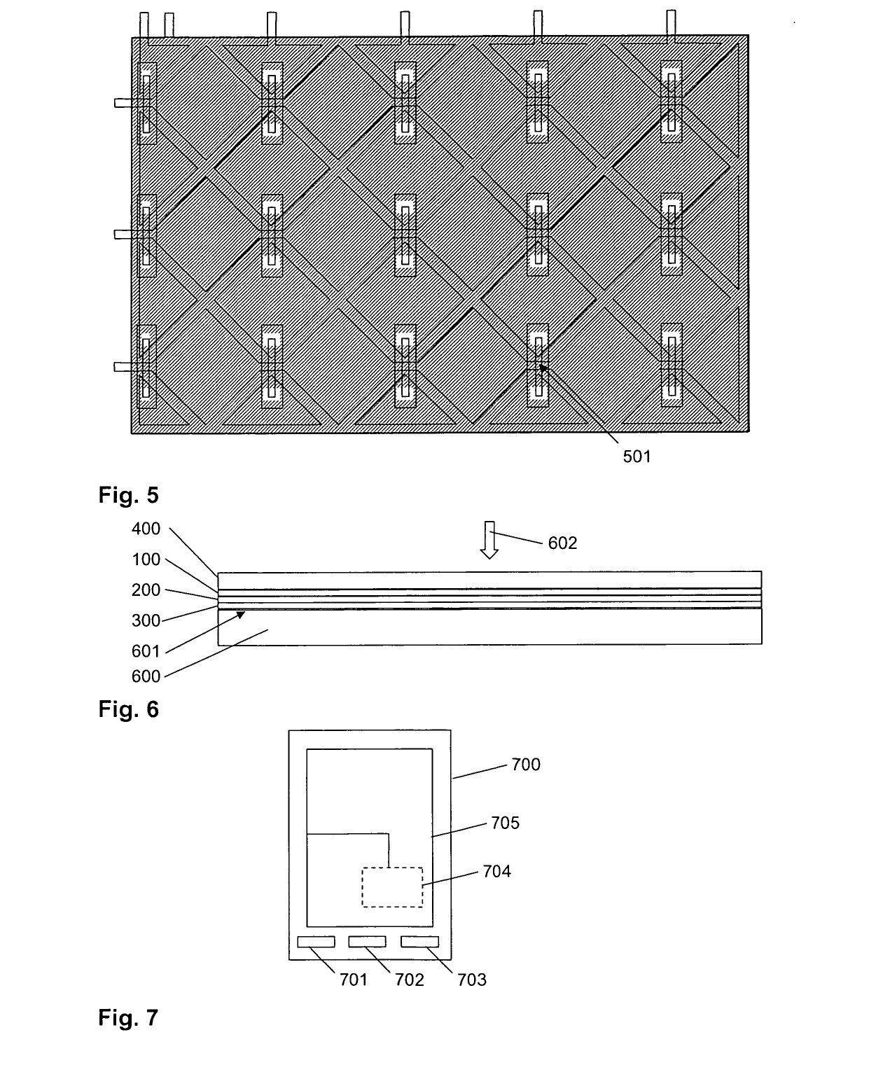

FIG. 6 shows a cross-sectional view of the above-described touch panel arranged on a display 600, for example a liquid crystal display 600. The display 600 has a display area 601 to display information for a user viewing the display 600 in the direction of arrow 602. The touch panel comprising the carrier panel 400 and the layers 100-300 is arranged on top of the display area 601. Due to the shielding area 302 in the second electrically conductive layer 300, electromagnetic disturbances emitted from the display 600 can be effectively shielded such that they do not influence a capacitance measuring of the fields 11-85 in the first electrically conductive layer 100. Therefore, when a user touches or approaches the carrier panel 400 in the direction of arrow 602, a position where the user touches or approaches to the touch panel can be determined by a change of capacitance determined by the fields 11-85 of the first electrically conductive layer 100. As the shielding layer 302 is integrated within the second electrically conductive layer 300 comprising also the bridging connections 301, no additional shielding layer between the touch panel and the display 600 is needed. This does not only reduce cost, but also reduces the number of process steps for producing the touch panel.

FIG. 7 shows a mobile device 700 comprising a user interface device 705 and a processing unit 704. The user interface device 705 comprises the structure shown in FIG. 6, i.e., the display 600 and the touch panel comprising the carrier panel 400 and the layers 100-300 arranged on top of the display 600. The processing unit is coupled to the display 600 and to the connector strips 101 of the touch panel. The connector strip 304 of the shielding area is coupled to a fixed potential, for example ground, of the mobile device 700. The mobile device 700 may comprise for example a so-called smart phone wherein the touch panel is the main input device for controlling the mobile device 700. However, the mobile device 700 may comprise additional user interface components, for example push buttons 701-703.

While exemplary embodiments have been described above, various modifications may be implemented in other embodiments. For example, the pattern of the fields 11-85 may comprise any suitable matrix or grid structure instead of the diamond-shaped fields shown in FIGS. 1 and 5.

Finally, it is to be understood that all the embodiments described above are considered to be comprised by the present invention as it is defined by the appended claims.

1-16. (canceled)

17. A touch panel, comprising:
a carrier panel,
a first electrically conductive layer arranged on a surface of the carrier panel comprising a first pattern of a plurality of electrically separated areas,
an electrically isolating layer arranged on the first electrically conductive layer comprising openings providing access to at least some of the electrically separated areas through the electrically isolating layer, and
a second electrically conductive layer arranged on the electrically isolating layer comprising a second pattern comprising a plurality of electrically separated areas, wherein the plurality of electrically separated areas of the second pattern comprises:
at least one bridging area electrically coupling at least two of the plurality of electrically separated areas of the first pattern through at least two of the openings of the electrically isolating layer, and
a shielding area electrically isolated from the plurality of electrically separated areas of the first pattern for electrically shielding the first pattern of the first electrically conductive layer.

18. The touch panel according to claim 17, wherein the shielding area covers essentially the whole first pattern apart from the at least one bridging area.

19. The touch panel according to claim 17, wherein the first and second electrically conductive areas are made of a visually transparent material,

20. The touch panel according to claim 19, wherein the visually transparent material comprises at least one of a group comprising indium tin oxide and graphene.

21. The touch panel according to claim 17, wherein the plurality of electrically separated areas of the first pattern comprises a plurality of first fields arranged in rows and a plurality of second fields arranged in columns, wherein the first fields in a common row are electrically coupled via connections within the first electrically conductive layer, and wherein the second fields in a common column are electrically coupled via the at least one bridging area of the second electrically conductive layer.

22. The touch panel according to claim 21, wherein the at least one bridging area is arranged across at least one of the connections within the first electrically conductive layer.

23. The touch panel according to claim 21, wherein the first fields and the second fields each have a diamond shape.

24. The touch panel according to claim 17, wherein the electrically isolating layer is sandwiched between the first and second electrically conductive layers.

25. The touch panel according to claim 17, wherein the electrically isolating layer and the first and second electrically conductive layers are arranged on a same side of the carrier panel,

26. The touch panel according to claim 17, wherein the carrier panel comprises a transparent material,

27. The touch panel according to claim 17, wherein the openings of the electrically isolating layer are cutouts formed in the electrically isolating layer.

28. A user interface device, comprising:
a display configured to display information for a user on a display area of a front panel of the display, and
a touch panel according to claim 17,

29. The user interface device according to claim 28, wherein the touch panel is arranged on the front panel of the display such that the second electrically conductive layer is arranged on the front panel, wherein the shielding area is coupled to a fixed electrical potential,

30. The user interface device according to claim 28, further comprising
a control unit coupled to the plurality of electrically separated areas of the first pattern and configured to determine based on a change of capacity of each of the plurality of electrically separated areas a position where a user approaches or touches the touch panel.

31. A mobile device comprising the user interface device according to claim 28.

32. The mobile device according to claim 31, wherein the mobile device is selected from a group comprising a mobile phone, a personal digital assistant, a media player, and a navigation system.
